(19) United States
(12) Patent Application Publication
(10) Pub. No.: US 2009/0215216 A1
(43) Pub. Date: Aug. 27, 2009

(54) Packaging method of image sensing device

(75) Inventors: Chi-Chih Huang, Tao-Yuan Hsien (TW); Chih-Yang Hsu, Tao-Yuan Hsien (TW)

Correspondence Address: BACON & THOMAS, PLLC, 625 SLATERS LANE, FOURTH FLOOR, ALEXANDRIA, VA, 22314-1176, US

(73) Assignee: Impac Technology Co., Ltd., Tao-Yuan Hsien (TW)

(21) Appl. No.: 12/071,424

(22) Filed: Feb. 21, 2008

(51) Int. Cl. H01L 21/00

(52) U.S. Cl. 438/65; 257/E21.001

(57) ABSTRACT

A packaging method for an image sensing device is disclosed. The packaging method includes the steps of a) mounting an image sensing module, having a light-receiving region exposed, on a substrate; b) connecting the image sensing module and the substrate via a plurality of bonding wires; c) forming a protecting layer on the light-receiving region of the image sensing module; d) forming a molding layer to seal the plurality of bonding wires; e) flattening the protecting layer and the molding layer; f) removing the protecting layer to expose the light-receiving region of the image sensing module; and g) forming a transparent lid.

### FIELD OF THE INVENTION

The present invention relates to a semiconductor packaging method, and more particularly, to a packaging method of an image sensing device.

### BACKGROUND OF THE INVENTION

In recent years, solid-state image sensors such as charge coupled devices (CCDs) or complementary metal oxide semiconductor (CMOS) image sensors have been widely applied to electronic products for converting light into electrical signals. The applications of image sensor components include monitors, cell phones, transcription machines, scanners, digital cameras, and so on.

Conventionally, these sensors have been packaged for use by mounting them to a substrate and enclosing them within a housing assembly. The housing assembly incorporates a transparent lid to allow light or other forms of radiation to be received by the sensor. The lid may be a flat window or shaped as a lens to provide optical properties. The substrate and housing are often formed from a ceramic material, and the lid is glass or a similar transparent substance attached to the housing by an adhesive. Due to the materials and structure involved, this packaging technique may be expensive and difficult to manufacture. Further, growing desire for portable electronic devices that will stand up to extreme environments raises concerns of durability and size.

FIG. 1 illustrates a prior art package structure of an image sensing component. As shown in FIG. 1, the image sensing or CCD chip 11 is sawed to a certain size and attached to paddle region 16 of a lead frame by using conductive adhesives 17. Dielectric wall 12, which is a dielectric film or a resin wall, is formed on the surface of the chip between bonding pads 10 and light-receiving region 19, and for electrical interconnection wire-bonding is then performed so that bonding pads 1O are interconnected to leads 15 by wire 14. Thereafter, transparent glass lid 13 is attached onto dielectric wall 12, and package body 18 is formed by a molding step in which the surface of glass lid 13 is open at its top surface of molding compound. Trimming and forming processes are then performed, and thus the plastic package for the image sensing device is produced.

In such conventional packages for a solid state image sensing device, since the dielectric wall is formed on the surface of the chip in the space between the bonding pads and the light-receiving region, it is considerably difficult to form the dielectric wall, which must have a certain area and height, in the considerably narrow space. Furthermore, since wire-bonding is utilized for the interconnections, a large space limitation is introduced.

In U.S. Pat. No. 5,773,323, a method for manufacturing a package is disclosed, wherein metallic bonding bumpers 22 are formed on bonding pads 20 of image sensing device 21, as shown in FIG. 2A, and inner leads 25 are positioned on and bonded to bonding bumpers 22 by a pressure welding, and thereby an electrical connection is accomplished. Thereafter, as illustrated in FIG. 2B, in order to form dielectric wall 23, which covers lead connection portions and has a certain volume and height, in the top surface of the chip but not light-receiving region 29, dielectric wall formation region is defined using a photoresist mask. A polymer is coated so that dielectric wall 23 is formed in the desired location. This polymer in the preferred embodiment is an adhesive dielectric thermoset-polymer, which may improve attachment to the image sensing device and the glass lid. The melting point of the bonding bumper material should be higher than that of the polymer. Alternatively, a suitable dielectric wall may be deposited and subsequently patterned by a photoresist mask. Subsequently, as illustrated in FIG. 2C, high light-transmission glass lid 24 is attached onto the dielectric wall, and thereby cavity 27 having a certain space above the device is formed. Successively, package body 26 is formed in a mold designed in a predetermined and desired shape, by a resin molding step in which the top surface of the package body is arranged at a top surface of the glass lid, as illustrated in FIG. 2D. However, in practice, the surface of the dielectric wall 23 can't be produced neatly and smoothly. When the high light-transmission glass lid 24 is attached onto the dielectric wall 23 on a slant without further grinding, the high light-transmission glass lid 24 won't transmit light correctly and a refraction angle thereof is influenced. Therefore, the solid state image sensing device according the above packaging method should fail easily.

Please refer to FIG. 3. U.S. Pat. No. 6,930,398 discloses a package structure for optical image sensing devices. An image sensing integrated circuit chip 31 includes a light sensing area 32 located on a light-receiving side 36 and a plurality of bonding pads arranged on the periphery along one side of the image sensing integrated circuit chip 31. In this case, bonding pads 33 may be arranged on the periphery along only one single side of the four sides of the image sensing integrated circuit chip 31. Instead of placing the light-sensing area at the center, this case places the light sensing area 32 near one corner of the chip. By doing this, the chip size as well as package size can be reduced. Meanwhile, an opaque, black glue frame 34 is coated on the outskirts of the light-sensing area 32 on the light-receiving side 36 of the image sensing integrated circuit chip 31. With the glue frame 34, a glass lid 35 is adhered on the light-receiving side 36 of the image sensing integrated circuit chip 31. In an ideal case, the glass lid 35 is in parallel with the light-sensing area 32. However, in practice, the glass lid 35 is hard to be in parallel with the light-sensing area 32 due to the surface of the glue frame 34 can't be produced neatly and smoothly, and therefore, may further cause light refraction.

Furthermore, in U.S. Pat. No. 7,195,940, a method for assembling at least one package containing an electronic device sensitive to light or other radiation is disclosed. The electronic device is mounted on a carrier substrate. At least one electrical interconnection is provided between a bond pad on the electronic device and the carrier substrate. Furthermore, a molded barrier is formed on the carrier substrate prior to mounting the electronic device, wherein the molded barrier surrounds a central exposed area that contains the electronic device and the at least one electrical interconnection. The central exposed area of the molded barrier is filled with a clear compound to form a transparent shell that encapsulates the electronic device, the bond pad, and the at least one electrical interconnection. Furthermore, a transparent lid is fixed over the central exposed area by applying an activated adhesive between an outer perimeter of the transparent lid and an inner perimeter of the molded barrier and setting the activated adhesive. However, the molding process disclosed by the prior art could damage the surface of the central exposed area of the electronic device and the at least one electrical interconnection. Certainly, the transparent lid might not be fixed in parallel with the surface of the electronic device without further flattening of the molding barrier which may cause light refraction while light passes through the transparent lid.

Although several packing methods of the prior art are technically feasible, in practice they are very inconvenient to implement. The molding process of the prior art might damage the central exposed area of the image sensing device and the bonding wires. On the other hand, the transparent lens might not be fixed in parallel with the surface of the image sensing device which may cause light refraction while light passes through the transparent lens. For fixing the transparent lid in parallel with the surface of the sensing device, flattening of the molding barrier could be introduced. However, the prior arts fail to disclose that, because the flattening process will damage the surface of the sensing device or the exposed bonding wires.

### SUMMARY OF THE INVENTION

Accordingly, the prior arts are limited by the above problems. It is an object of the present invention to provide a packaging method of an image sensing device, wherein a flattening process of the molding compound is introduced for flattening the surface of the molding compound, thereby fixing the transparent lens in parallel with the surface of the image sensing device so as to avoid light refraction while light passes through the transparent lens of the image sensing device.

In accordance with an aspect of the present invention, a packaging method for an image sensing device, includes the steps of a) mounting an image sensing module, having a light-receiving region exposed, on a substrate; b) connecting the image sensing module and the substrate via a plurality of bonding wires; c) forming a protecting layer on the light-receiving region of the image sensing module; d) forming a molding layer to seal the plurality of bonding wires; e) flattening the protecting layer and the molding layer to obtain an entire flatten surface; f) removing the protecting layer to expose the light-receiving region of the image sensing module; and g) forming a transparent lid.

Preferably, the step c) further includes a step of cl) forming a barrier on the image sensing module, wherein the barrier is disposed around the light-receiving region of the image sensing module.

Preferably, the image sensing module includes complementary metal oxide semiconductor (CMOS) image sensor or charge coupled device (CCD) image sensor.

Preferably, the substrate includes aluminum nitride ceramic, fiberglass-reinforced epoxy resin, or bismaleimide-triazine resin.

Preferably, the protecting layer and the barrier are formed by transfer molding, pot molding, injection molding, photolithographic process, exposure development process, laser cutting process, or stereolithographic process.

Preferably, the protecting layer and the barrier are defined using a photoresist mask.

Preferably, the protecting layer and the barrier are made of epoxy, solder mask, or photoresist.

Preferably, a cavity is formed between the transparent lid and the light-receiving region of the image sensing module.

In accordance with another aspect of the present invention, the packaging method for an image sensing device, could include the steps of: a) providing an image sensing module having a light-receiving region; b) forming a protecting layer on the light-receiving region of the image sensing module; c) forming a molding layer around the protecting layer without covering the protecting layer; d) flattening the protecting layer and the molding layer; e) removing the protecting layer to expose the light-receiving region of the image sensing module; and f) forming a transparent lid.

### BRIEF DESCRIPTION OF THE DRAWING

The above objects and advantages of the present invention will become more readily apparent to those ordinarily skilled in the art after reviewing the following detailed description and accompanying drawings, in which:

FIG. 1 illustrates a prior art package structure of an image sensing component;

FIGS. 2A-2D illustrate a packaging method of an image sensing device according to the prior art;

FIG. 3 illustrates another package structure of an image sensing component according to the prior art; and

FIGS. 4A-4I illustrate an embodiment of packaging method for an image sensing device according to the present invention.

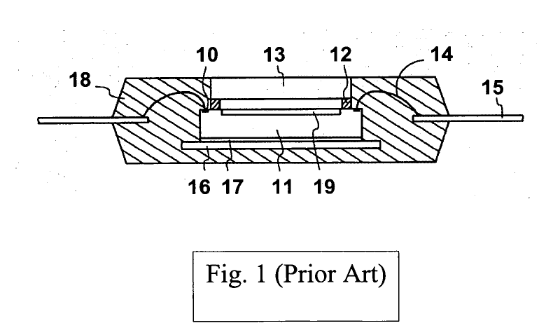

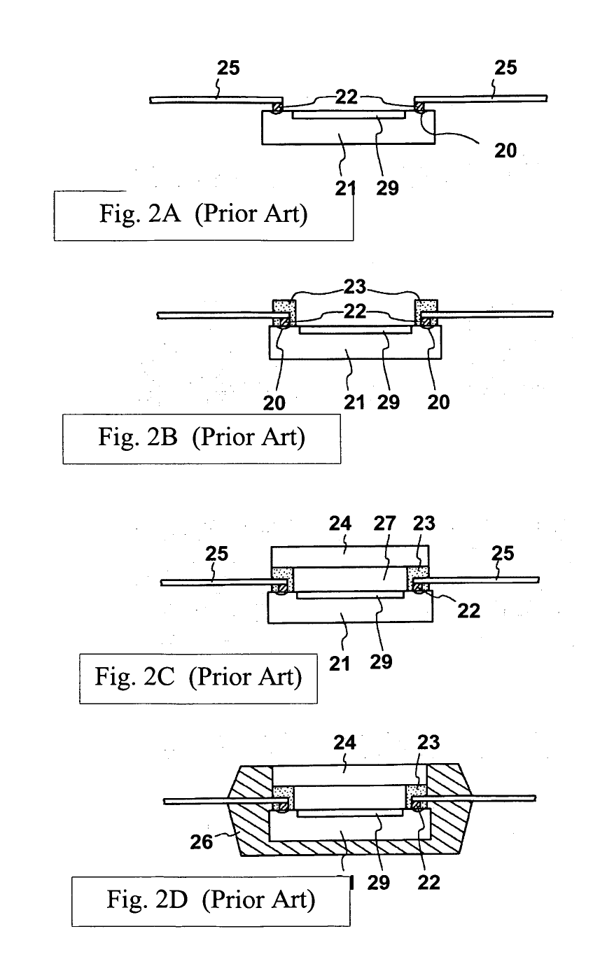

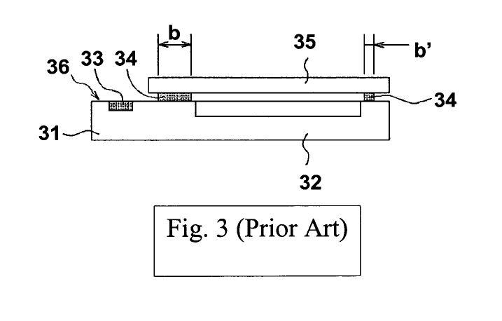

### DETAILED DESCRIPTION OF THE PREFERRED EMBODIMENT

The present invention will now be described more specifically with reference to the following embodiment. It is to be noted that the following descriptions of preferred embodiment of this invention are presented herein for purpose of illustration and description only; it is not intended to be exhaustive or to be limited to the precise form disclosed.

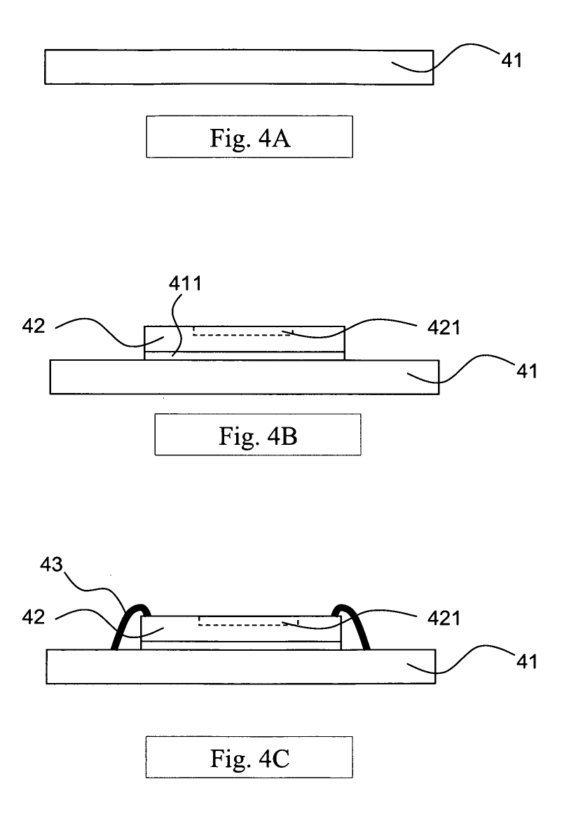

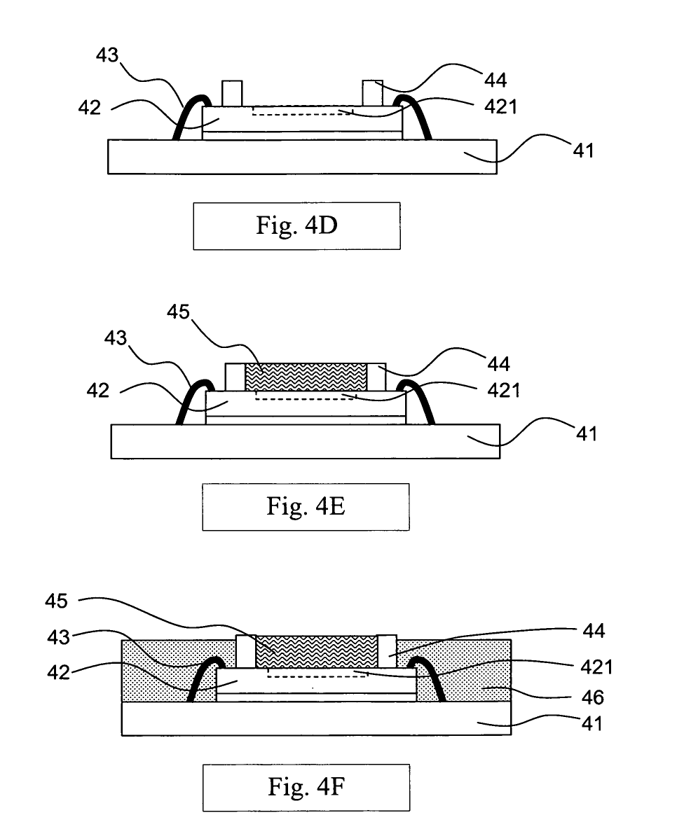

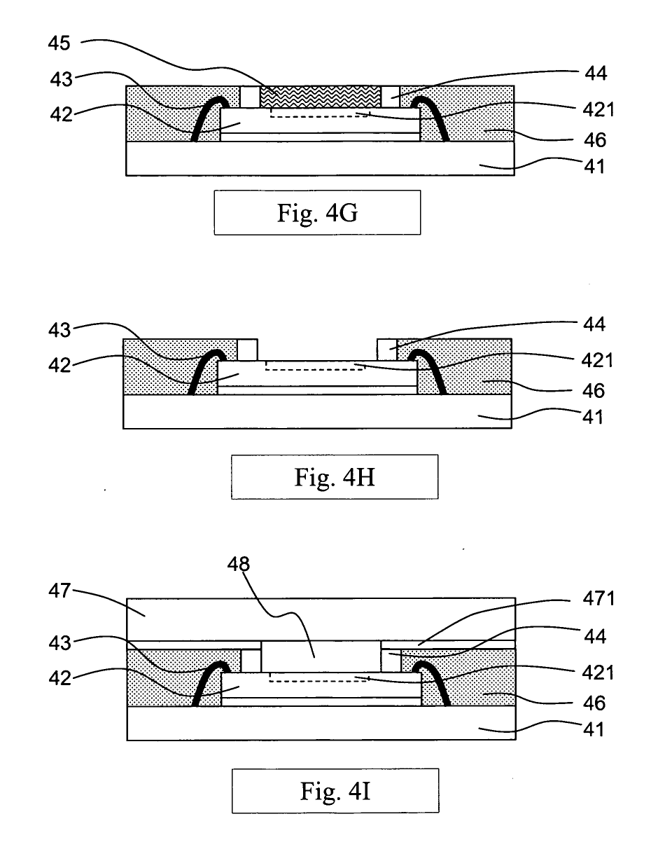

Please refer to FIGS. 4A-4I. They illustrate an embodiment of packaging method for an image sensing device according to the present invention. Firstly, please refer to FIG. 4A. There is a substrate 41 which could be made by plastic, fiberglass-reinforced epoxy resin, or bismaleimide-triazine resin. Furthermore, the substrate 41 could also be made of aluminum nitride ceramic for improving the thermal conductivity. As shown in FIG. 4B, an image sensing module 42, having a light-receiving region 421 exposed, is mounted on a substrate 41. The image sensing module 42 is mounted on the substrate 41 in a conventional manner such as tape lamination process. In this embodiment, the image sensing module 42 is mounted on the substrate 41 via an adhesive layer 411. Usually, there are a lot of connecting pads (not shown) disposed on the image sensing module 42 and the substrate 41. Accordingly, those connecting pads of the image sensing module 42 and the substrate 41 are conducted via a plurality of bonding wires 43, as shown in FIG. 4C. After that, a barrier 44 is formed on the image sensing module 42, as shown in FIG. 4D. The barrier 44 is disposed around the light-receiving region 421 of the image sensing module 42. Moreover, a protecting layer 45 is further formed over the light-receiving region 421 of the image sensing module 42 for protecting the light-receiving region 421 of the image sensing module 42 during the following molding process, as shown in FIG. 4E. Then, the molding process could be executed. Molding compound is introduced to form a molding layer 46; and the plurality of bonding wires 43 are completely sealed by the molding layer 46, as shown in FIG. 4F. Meanwhile, the entire surface of the barrier 44, the protecting layer 45 and the molding layer 46 might not be flat or smooth. The barrier 44, the protecting layer 45 and the molding layer 46 can be ground partially to obtain an entire flatten surface, as shown in FIG. 4G After flattening, the protecting layer 45 can be removed to expose the light-receiving region 421 of the image sensing module 42, as shown in FIG. 4H. Finally, a transparent lid 47 is covered on the entire flatten surface, and adhered onto the barrier 44 and the molding layer 46 via an adhesive compound 471, as shown in FIG. 4I.

In practice, the image sensing module 42 of the present invention could be complementary metal oxide semiconductor (CMOS) image sensor or charge coupled device (CCD) image sensor. In this embodiment, the protecting layer 45 and the barrier 44 can be made of epoxy, solder mask, or photoresist, and can be formed by transfer molding, pot molding, injection molding, photolithographic process, exposure development process, laser cutting process, or stereolithographic process. Due to the fact that the barrier 44 and the protecting layer 45 each has a certain volume and height, they are usually defined using a photoresist mask. Furthermore, a cavity 48 is formed under the transparent lid 47 above the light-receiving region 421 of the image sensing module 42. Different from the prior art, there is a protecting layer 45 introduced to protect the light-receiving region 421 of the image sensing module 42 during the molding and flattening process, and a flattening process is introduced to flatten the top surface of the barrier 44 and the molding layer 46. Thus, the damages to the light-receiving region 421 of the image sensing module 42 and the plurality of bonding wires 43 is prevented. Then, the transparent lid 47 is disposed on a flat surface and in parallel with the surface of the light-receiving region 421 of the image sensing module 42 so as to avoid light refraction while light passes through the transparent lid 47 of the image sensing module 42. Besides, the flattening process can also be used to adjust the height of the cavity 48 to fit different needs.

In accordance with another aspect, the present invention further discloses a packaging method for an image sensing device with the following steps. First of all, a substrate 41 mounted with an image sensing module 42, having a light-receiving region 421 exposed and a plurality of bonding wires 43 electrically connected with the substrate 41 is provided, as shown in FIG. 4C. Next, a protecting layer 45 over the light-receiving region 421 of the image sensing module 42 is formed. Then, a barrier 44 is formed on the image sensing module 42. The barrier 44 is disposed around the light-receiving region 421 of the image sensing module 42, and the obtained structure is illustrated as FIG. 4E. Later, a molding layer 46 to seal the plurality of bonding wires 43 is formed, as shown in FIG. 4F. After that, the protecting layer 45, the barrier 44 and the molding layer 46 are grinded partially to obtain an entire flatten surface, as shown in FIG. 4G Then, the protecting layer 45 is removed to expose the light-receiving region 421 of the image sensing module 42, as shown in FIG. 4H. Finally, a transparent lid 47 is covered on the entire flatten surface, as shown in FIG. 41.

Similarly, the image sensing module 42 of the present invention could be complementary metal oxide semiconductor (CMOS) image sensor or charge coupled device (CCD) image sensor. The protecting layer 45 and the barrier 44 can be made of epoxy, solder mask, or photoresist, and can be formed by transfer molding, pot molding, injection molding, photolithographic process, exposure development process, laser cutting process, or stereolithographic process. Different from the above mentioned embodiment, the barrier 44 can be formed after the protecting layer 45. Certainly, a cavity 48 is formed under the transparent lid 47 above the light-receiving region 421 of the image sensing module 42, as shown in FIG. 41. Due to the protecting layer 45 introduced to protect the light-receiving region 421 of the image sensing module 42 during the molding process; and the flattening process introduced to flatten the top surface of the barrier 44 and the molding layer 46; the damages of the light-receiving region 421 of the image sensing module 42 and the plurality of bonding wires 43 is prevented; and the transparent lid 47 is disposed on a flat surface and in parallel with the surface of the light-receiving region 421 of the image sensing module 42 so as to avoid light refraction while light passes through the transparent lid 47 of the image sensing module 42. Furthermore, the flattening process can also be used to adjust the height of the cavity 48 to fit different needs.

In conclusion, the present invention introduces a flattening process into a packaging method of an image sensing device so that the top surface of the barrier and the molding layer can be flatten, thereby fixing the transparent lens in parallel with the surface of the image sensing device so as to avoid light refraction while light passes through the transparent lens of the image sensing device. Besides, the flattening process can also be used to adjust the height of the cavity 48 to fit different needs.

While the invention has been described in terms of what is presently considered to be the most practical and preferred embodiment, it is to be understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A packaging method for an image sensing device, comprising the steps of:
a) mounting an image sensing module, having a light-receiving region exposed, on a substrate;
b) connecting said image sensing module and said substrate via a plurality of bonding wires;
c) forming a protecting layer on said light-receiving region of said image sensing module;
d) forming a molding layer to seal said plurality of bonding wires;
e) flattening said protecting layer and said molding layer;
f) removing said protecting layer to expose said light-receiving region of said image sensing module; and
g) forming a transparent lid.

2. The packaging method according to claim 1, wherein said image sensing module comprises complementary metal oxide semiconductor (CMOS) image sensor or charge coupled device (CCD) image sensor.

3. The packaging method according to claim 1, wherein said substrate comprises aluminum nitride ceramic, fiberglass-reinforced epoxy resin, or bismaleimide-triazine resin.

4. The packaging method according to claim 1, wherein said protecting layer is formed by transfer molding, pot molding, injection molding, photolithographic process, exposure development process, laser cutting process, or stereolithographic process.

5. The packaging method according to claim 1, wherein said protecting layer is defined using a photoresist mask.

6. The packaging method according to claim 1, wherein said protecting layer is made of epoxy, solder mask, or photoresist.

7. The packaging method according to claim 1, wherein said step c) further comprises a step of:
c1) forming a barrier on said image sensing module, wherein said barrier is disposed around said light-receiving region of said image sensing module.

8. The packaging method according to claim 7, wherein said barrier is formed by transfer molding, pot molding, injection molding, photolithographic process, exposure development process, laser cutting process, or stereolithographic process.

9. The packaging method according to claim 7, wherein said barrier is defined using a photoresist mask.

10. The packaging method according to claim 7, wherein said barrier is made of epoxy, solder mask, or photoresist.

11. The packaging method according to claim 1, wherein a cavity is formed between said transparent lid and said light-receiving region of said image sensing module.

12. A packaging method for an image sensing device, comprising the steps of:
a) providing an image sensing module having a light-receiving region;
b) forming a protecting layer on said light-receiving region of said image sensing module;
c) forming a molding layer around said protecting layer without covering said protecting layer;
d) flattening said protecting layer and said molding layer;
e) removing said protecting layer to expose said light-receiving region of said image sensing module; and
f) forming a transparent lid.

13. The packaging method according to claim 12, wherein said image sensing module is mounted on a substrate and has a plurality of bonding wires electrically connected with said substrate.

14. The packaging method according to claim 13, wherein said substrate comprises aluminum nitride ceramic, fiberglass-reinforced epoxy resin, or bismaleimide-triazine resin.

15. The packaging method according to claim 12, wherein said protecting layer is formed by transfer molding, pot molding, injection molding, photolithographic process, exposure development process, laser cutting process, or stereolithographic process.

16. The packaging method according to claim 12, wherein said protecting layer is defined using a photoresist mask.

17. The packaging method according to claim 12, wherein said protecting layer is made of epoxy, solder mask, or photoresist.

18. The packaging method according to claim 12, wherein said step b) further comprises a step of:
b1) forming a barrier on said image sensing module, wherein said barrier is disposed around said light-receiving region of said image sensing module.

19. The packaging method according to claim 18, wherein said barrier is formed by transfer molding, pot molding, injection molding, photolithographic process, exposure development process, laser cutting process, or stereolithographic process.

20. The packaging method according to claim 18, wherein said barrier is defined using a photoresist mask.

21. The packaging method according to claim 18, wherein said barrier is made of epoxy, solder mask, or photoresist.

22. The packaging method according to claim 12, wherein said image sensing module comprises complementary metal oxide semiconductor (CMOS) image sensor or charge coupled device (CCD) image sensor.

23. The packaging method according to claim 12, wherein a cavity is formed between said transparent lid and said light-receiving region of said image sensing module.
